(19) United States
(12) Patent Application Publication
(10) Pub. No.: US 2022/0149111 A1
(43) Pub. Date: May 12, 2022

(54) DISPLAY DEVICE

(71) Applicant: Samsung Display Co., Ltd., Yongin-si (KR)

(72) Inventors: Eun Bee LEE, Hwaseong-si (KR); Su Jeong KIM, Seoul (KR)

(21) Appl. No.: 17/445,467

(22) Filed: Aug. 19, 2021

(30) Foreign Application Priority Data
Nov. 6, 2020 (KR) 10-2020-0147302

(51) Int. Cl. H01L 27/15; H01L 33/24; H01L 33/38; H01L 33/44; H01L 33/50

(52) U.S. Cl. CPC H01L 27/156; H01L 33/24; H01L 2933/0091; H01L 33/44; H01L 33/50; H01L 33/38

(57) ABSTRACT

A display device is provided. The display device includes a first substrate, a first electrode and a second electrode on the first substrate and spaced apart from each other, a first insulating layer on the first electrode and the second electrode, light-emitting elements on the first insulating layer and having ends on the first electrode and the second electrode, respectively, and a second insulating layer on the first insulating layer and the light-emitting elements, and defining openings exposing the ends of the light-emitting elements, wherein the second insulating layer is configured to transmit light in a wavelength range of light emitted by the light-emitting elements, and configured to block transmission of light outside of the wavelength range.

### CROSS-REFERENCE TO RELATED APPLICATION

This application claims priority to, and the benefit of, Korean Patent Application No. 10-2020-0147302 filed on Nov. 6, 2020 in the Korean Intellectual Property Office, the contents of which in its entirety are herein incorporated by reference.

### BACKGROUND

### 1. Field

The present disclosure relates to a display device.

### 2. Description of the Related Art

Display devices become more and more important as multimedia technology evolves. Accordingly, a variety of types of display devices such as organic light-emitting display (OLED) devices and liquid-crystal display (LCD) devices are currently used.

Display devices are for displaying images, and include a display panel such as an organic light-emitting display panel or a liquid-crystal display panel. Among them, light-emitting display panel may include light-emitting elements. For example, light-emitting diodes (LEDs) may include an organic light-emitting diode using an organic material as a luminescent material, and an inorganic light-emitting diode using an inorganic material as a luminescent material.

### SUMMARY

Aspects of the present disclosure provide a display device that can reduce reflection of external light.

According to some embodiments of the present disclosure, a display device includes an insulating layer that transmits lights emitted from light-emitting elements while blocking transmission of other lights. The display device can reduce reflection of external light and can improve visibility.

It should be noted that aspects of the present disclosure are not limited to those described above and other aspects of the present disclosure will be apparent to those skilled in the art from the following descriptions.

According to some embodiments, a display device includes a first substrate, a first electrode and a second electrode on the first substrate and spaced apart from each other, a first insulating layer on the first electrode and the second electrode, light-emitting elements on the first insulating layer and having ends on the first electrode and the second electrode, respectively, and a second insulating layer on the first insulating layer and the light-emitting elements, and defining openings exposing the ends of the light-emitting elements, wherein the second insulating layer is configured to transmit light in a wavelength range of light emitted by the light-emitting elements, and configured to block transmission of light outside of the wavelength range.

The light emitted from the light-emitting elements may have a center wavelength range from about 400 nm to about 500 nm.

The openings of the second insulating layer may include a first opening that exposes first ends of the light-emitting elements and that partially overlaps the first electrode, and a second opening that exposes second ends of the light-emitting elements and that partially overlaps the second electrode, wherein the second insulating layer includes a pattern portion between the first opening and the second opening and on the light-emitting elements.

A thickness of the second insulating layer may range from about 0.1 μm to about 1 μm.

A width of the pattern portion may be less than a length of the light-emitting elements.

The display device may further include a first contact electrode on the first electrode and the second insulating layer, and in contact with the first ends of the light-emitting elements, and a second contact electrode on the second electrode and the second insulating layer, and in contact with the second ends of the light-emitting elements, wherein the first contact electrode and the second contact electrode are spaced apart from each other on the pattern portion of the second insulating layer.

The first insulating layer may expose a part of an upper surface of each of the first electrode and the second electrode, wherein the first contact electrode and the second contact electrode are in direct contact with the first electrode and the second electrode, respectively.

The second insulating layer may include parts directly on the first electrode and the second electrode.

The display device may further include first banks between the first electrode and the first substrate, and between the second electrode and the first substrate, respectively, wherein the first opening and the second opening partially overlap different ones of the first banks, respectively.

The display device may further include a second bank on the first insulating layer, surrounding an emission area in which the light-emitting elements are located, and having a part of the second insulating layer thereon.

The second bank may surround a sub-area spaced apart from the emission area and in which the light-emitting elements are not located, wherein the first electrode and the second electrode are located across the emission area and the sub-area.

The first insulating layer may include a first contact exposing a part of an upper surface of the first electrode in the sub-area, and a second contact exposing a part of an upper surface of the second electrode in the sub-area, wherein the second insulating layer further includes a third opening overlapping the first contact, and a fourth opening overlapping the second contact.

The second insulating layer may further include a fifth opening formed in the sub-area, wherein the first electrode and the second electrode are not located in the fifth opening.

The display device may further include a wavelength conversion layer on the light-emitting elements, and a color filter layer on the wavelength conversion layer, and configured to transmit light outside of the wavelength range of light emitted by the light-emitting elements, and to block transmission of light within the wavelength range of the light emitted by the light-emitting elements.

According to other embodiments, a display device includes an emission area and a sub-area spaced apart from the emission area in a first direction, a first electrode and a second electrode extended in the first direction, and spaced apart from each other in a second direction, a first insulating layer partially covering the first electrode and the second electrode, light-emitting elements on the first electrode and the second electrode, and arranged in the first direction in the emission area, and a second insulating layer on the first insulating layer and on the light-emitting elements, defining openings exposing ends of the light-emitting elements, and including a pattern portion extended in the first direction between the openings and on the light-emitting elements, wherein the light emitted from the light-emitting elements has a central wavelength range from about 400 nm to about 500 nm, and wherein the second insulating layer is configured to transmit light having a central wavelength range from about 400 nm to about 500 nm while blocking other lights.

The second insulating layer may be on the emission area and the sub-area, and may define a first opening extended in the first direction and partially overlapping the first electrode, and a second opening extended in the first direction and partially overlapping the second electrode in the emission area.

The first insulating layer may include a first contact exposing a part of an upper surface of the first electrode, and a second contact exposing a part of an upper surface of the second electrode in the sub-area, wherein the second insulating layer further defines a third opening overlapping the first contact, and a fourth opening overlapping the second contact.

The display device may further include a first contact electrode on the first electrode, and in contact with first ends of the light-emitting elements exposed by the first opening and with the first electrode exposed by the third opening and the first contact, and a second contact electrode on the second electrode, and in contact with second ends of the light-emitting elements exposed by the second opening and with the second electrode exposed by the fourth opening and the second contact.

The second insulating layer may further define a fifth opening formed in the sub-area, wherein the first electrode and the second electrode are not located in the fifth opening.

A width of the pattern portion may be less than a length of the light-emitting elements.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view of a display device according to some embodiments of the present disclosure.

FIG. 2 is a plan view showing a pixel of a display device according to some embodiments of the present disclosure.

FIG. 3 is a plan view showing a first sub-pixel of FIG. 2.

FIG. 4 is a cross-sectional view taken along the line Q1-Q1′ of FIG. 3.

FIG. 5 is a view showing a light-emitting element according to some embodiments of the present disclosure.

FIG. 6 is a plan view showing a layout of a second insulating layer in a display device according to some embodiments of the present disclosure.

FIG. 7 is a cross-sectional view schematically showing paths of light in a display device according to some embodiments.

FIG. 8 is a plan view showing a sub-pixel of a display device according to other embodiments of the present disclosure.

FIG. 9 is a plan view schematically showing arrangement of a second insulating layer in the display device of FIG. 8.

FIG. 10 is a cross-sectional view taken along the line Q2-Q2′ of FIG. 8.

FIG. 11 is a cross-sectional view taken along the line Q3-Q3′ of FIG. 8.

FIG. 12 is a cross-sectional view taken along the line Q4-Q4′ of FIG. 8.

FIG. 13 is a cross-sectional view showing a part of a display device according to other embodiments of the present disclosure.

FIG. 14 is a cross-sectional view of a display device according to other embodiments of the present disclosure.

FIG. 15 is a cross-sectional view schematically showing paths of light in one of the sub-pixels of FIG. 14.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts not related to the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, the term “and/or” includes any and all combinations of one or more of the associated listed items. For example, the expression such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

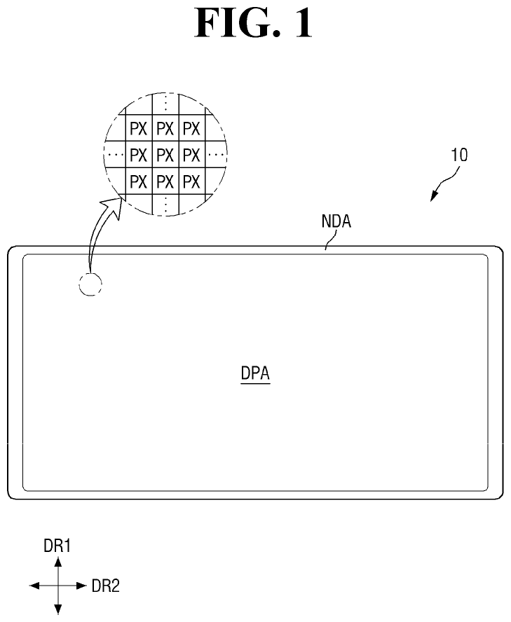

FIG. 1 is a plan view of a display device according to some embodiments of the present disclosure.

Referring to FIG. 1, the display device 10 displays a moving image or a still image. The display device 10 may refer to any electronic device that provides a display screen. For example, the display device 10 may include a television set, a laptop computer, a monitor, an electronic billboard, the Internet of Things devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console, a digital camera, a camcorder, etc.

The display device 10 includes a display panel for providing a display screen. Examples of the display panel may include an inorganic light-emitting diode display panel, an organic light-emitting display panel, a quantum-dot light-emitting display panel, a plasma display panel, a field emission display panel, etc. In the following description, an inorganic light-emitting diode display panel is employed as an example of the display panel of the display device 10, but the present disclosure is not limited thereto. Any other display panel may be employed as long as the technical idea of the present disclosure may be equally applied.

The shape of the display device 10 may be modified in a variety of ways. For example, the display device 10 may have shapes such as a rectangle with longer lateral sides, a rectangle with longer vertical sides, a square, a quadrangle with rounded corners (vertices), other polygons, a circle, etc. The shape of a display area DPA of the display device 10 may also be similar to the overall shape of the display device 10. In the example shown in FIG. 1, the display device 10 has a rectangular shape with the longer sides in a second direction DR2.

The display device 10 may include the display area DA and a non-display area NDA. In the display area DPA, images may be displayed. In the non-display area NDA, images are not displayed. The display area DPA may be referred to as an active area, while the non-display area NDA may also be referred to as an inactive area. The display area DPA may generally occupy the majority of the center of the display device 10.

The display area DPA may include a plurality of pixels PX. The plurality of pixels PX may be arranged in a matrix. The shape of each pixel PX may be, but is not limited to, a rectangle or a square when viewed from the top. Each pixel may have a diamond shape having sides inclined with respect to a direction. The pixels PX may be arranged in stripes and PENTILE™ pattern alternately. PENTILE™ is a registered trademark of Samsung Display Co., Ltd., Republic of Korea. Each of the pixels PX may include at least one light-emitting element that emits light of a corresponding (e.g., particular) wavelength range to represent a color.

The non-display area NDA may be located around the display area DPA. The non-display area NDA may surround the display area DPA entirely or partially. The display area DPA may have a rectangular shape, and the non-display area NDA may be adjacent to the four sides of the display area DPA. The non-display area NDA may form the bezel of the display device 10. Lines or circuit drivers included in the display device 10 may be located in each of the non-display area NDA, or external devices may be mounted.

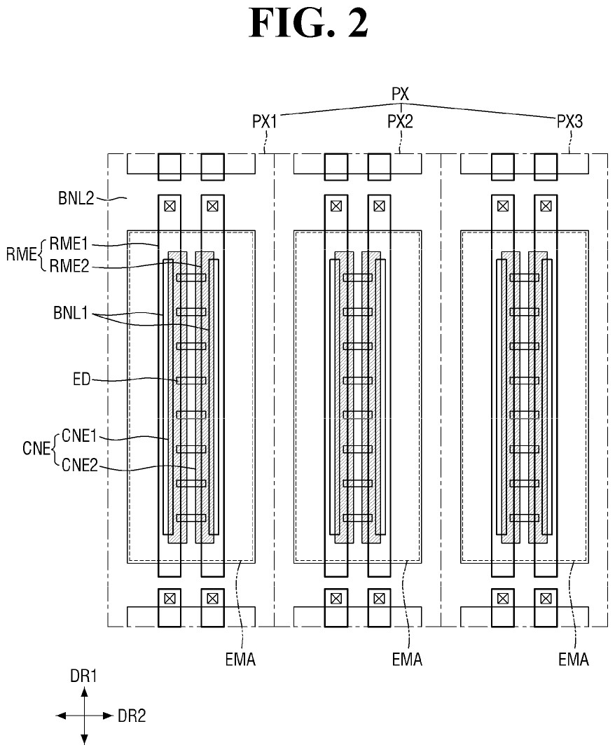

FIG. 2 is a plan view showing a pixel of a display device according to some embodiments of the present disclosure.

Referring to FIG. 2, each of the plurality of pixels PX of the display device 10 may include a plurality of sub-pixels PXn, where n is an integer from one to three. For example, a pixel PX may include a first sub-pixel PX1, a second sub-pixel PX2, and a third sub-pixel PX3. The first sub-pixel PX1 may output light of a first color, the second sub-pixel PX2 may output light of a second color, and the third sub-pixel PX3 may output light of a third color. For example, the first color may be red, the second color may be green, and the third color may be blue. It is, however, to be understood that the present disclosure is not limited thereto. In some embodiments, all the sub-pixels PXn may emit light of the same color. Although the single pixel PX includes three sub-pixels PXn in the example shown in FIG. 2, the present disclosure is not limited thereto. The pixel PX may include two sub-pixels PXn or four or more sub-pixels PXn.

Each of the sub-pixels PXn of the display device 10 may include an emission area EMA and a non-emission area. In the emission area EMA, the light-emitting elements ED may be located to emit light of a corresponding wavelength. In the non-emission area, no light-emitting element ED is located and light emitted from the light-emitting elements ED do not reach and thus no light exits therefrom. The emission area may include an area in which the light-emitting elements ED are located, and may include an area adjacent to the light-emitting elements ED where light that is emitted from the light-emitting element ED exits.

It is, however, to be understood that the present disclosure is not limited thereto. In some embodiments, the emission area may also include an area in which light emitted from the light-emitting element ED is reflected or refracted by other elements to exit. The plurality of light-emitting elements ED may be located in each of the sub-pixels PXn, and the emission area may include the area where the light-emitting elements are located and the adjacent area.

Although the emission areas EMA of the sub-pixels PXn have substantially the uniform area in the example shown in the drawings, the present disclosure is not limited thereto. In some embodiments, the emission areas EMA of the sub-pixels PXn may have different areas depending on a color or wavelength range of light emitted from the light-emitting diodes ED located in the respective sub-pixels.

The second bank BNL2 may be located in a lattice pattern on the entire surface of the display area DPA including portions extended in the first direction DR1 and the second direction DR2 when viewed from the top. The second bank BNL2 may be located along the border of each of the sub-pixels PXn to distinguish adjacent sub-pixels PXn from one another. In addition, the second bank BNL2 may be located to surround the emission area EMA located in each of the sub-pixels PXn to distinguish between them.

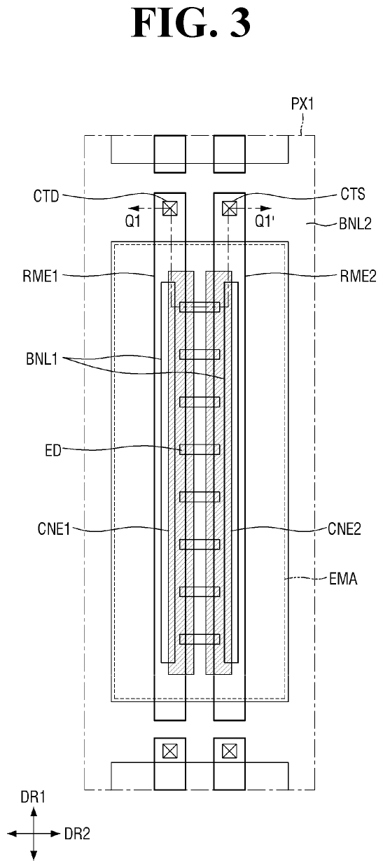

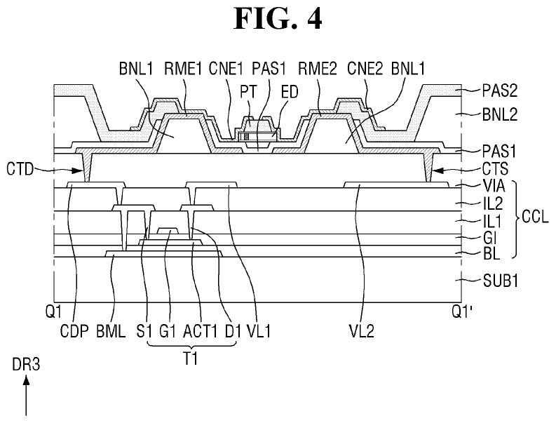

FIG. 3 is a plan view showing a first sub-pixel of FIG. 2, and FIG. 4 is a cross-sectional view taken along the line Q1-Q1′ of FIG. 3. FIG. 3 shows a first sub-pixel PX1 included in one pixel PX, and FIG. 4 shows a cross section passing through both ends of different light-emitting diodes ED located in the first sub-pixel PX1.

Referring to FIGS. 3 and 4 in conjunction with FIG. 2, the display device 10 may include a first substrate SUB1, a semiconductor layer located on the first substrate SUB1, a plurality of conductive layers, and a plurality of insulating layers. The semiconductor layer, the conductive layers, and the insulating layers may form a circuit layer CCL and a display element layer of the display device 10.

The first substrate SUB1 may be an insulating substrate. The first substrate SUB1 may be made of an insulating material such as glass, quartz, and a polymer resin. The first substrate SUB1 may be either a rigid substrate or a flexible substrate that may be bent, folded, or rolled.

A first conductive layer may be located on the first substrate SUB1. The first conductive layer includes a bottom metal layer BML. The bottom metal layer BML is located to overlap an active layer ACT1 of a first transistor T1. The bottom metal layer BML may include a material that blocks light, and thus may reduce or prevent light from entering the active layer ACT1 of the first transistor T1. It is, however, to be noted that the bottom metal layer BML may be eliminated in other embodiments.

A buffer layer BL may be located on the bottom metal layer BML and the first substrate SUB1. The buffer layer BL may be formed on the first substrate SUB1 to protect the transistors of the pixel PX from moisture permeating through the first substrate SUB1 that is susceptible to moisture permeation, and may also provide a flat surface.

The semiconductor layer is located on the buffer layer BL. The semiconductor layer may include the active layer ACT1 of the first transistor T1. The active layer ACT1 may be located to partially overlap with a gate electrode G1 of a second conductive layer, which will be described later.

The semiconductor layer may include polycrystalline silicon, monocrystalline silicon, an oxide semiconductor, etc. In other embodiments, the semiconductor layer may include polycrystalline silicon. The oxide semiconductor may be an oxide semiconductor containing indium (In). For example, the oxide semiconductor may be at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), indium-gallium zinc tin oxide (IGZTO), etc.

Although only one first transistor T1 is located in the sub-pixel PXn of the display device 10 in the drawing, the present disclosure is not limited thereto. A greater number of transistors may be included in the display device 10.

A first gate insulator GI is located on the semiconductor layer and the buffer layer BL. The first gate insulator GI may work as a gate insulating film of the first transistor T1.

The second conductive layer is located on the first gate insulating layer GI. The second conductive layer may include a gate electrode G1 of the first transistor T1. The gate electrode G1 may be located so that it overlaps a channel region of the active layer ACT1 in the thickness direction (e.g., a third direction DR3). In some embodiments, the second conductive layer may further include a capacitor electrode of a storage capacitor.

A first interlayer dielectric layer IL1 is located on the second conductive layer. The first interlayer dielectric layer IL1 may work as an insulating film between the second conductive layer and other layers located thereon, and may protect the second conductive layer.

A third conductive layer is located on the first interlayer dielectric layer IL1. The third conductive layer may include a first source electrode S1 and a first drain electrode D1 of the first transistor T1.

The first source electrode S1 and the first drain electrode D1 of the first transistor T1 may be in contact with the active layer ACT1 through contact holes penetrating through the first interlayer dielectric layer IL1 and the first gate insulating layer GI. In addition, the first source electrode S1 may be in contact with the bottom metal layer BML through another contact hole. In some embodiments, the third conductive layer may further include a plurality of data lines or the capacitance electrode of the storage capacitor.

A second interlayer dielectric layer IL2 is located on the third conductive layer. The second interlayer dielectric layer IL2 may serve as an insulating layer between the third conductive layer and other layers located thereon, and may protect the third conductive layer.

A fourth conductive layer is located on the second interlayer dielectric layer IL2. The fourth conductive layer may include a first voltage line VL1, a second voltage line VL2, and a first conductive pattern CDP. A high-level voltage (or a first supply voltage) may be applied to the first voltage line VL1 to be transmitted to a first electrode RME1 through the first transistor T1, and a low-level voltage (or a second supply voltage) may be applied to the second voltage line VL2 to be transmitted to a second electrode RME2.

The first electrode pattern CDP may be electrically connected to the first transistor T1. The first conductive pattern CDP may also be connected to the first electrode RME1 to be described later. The first transistor D1 may transfer the first supply voltage applied from the first voltage line VL1 to the first electrode RME1.

The buffer layer BL, the first gate insulator GI, the first interlayer dielectric layer IL1 and the second interlayer dielectric layer IL2 may be made up of multiple inorganic layers alternately stacked on one another. For example, the buffer layer BL, the first gate insulator GI, the first interlayer dielectric layer IL1, and the second interlayer dielectric layer IL2 may be made up of a double layer in which inorganic layers including at least one of silicon oxide (SiOx), silicon nitride (SiNx), and silicon oxynitride (SiON) are stacked on one another or multiple layers in which they are alternately stacked on one another. It is, however, to be understood that the present disclosure is not limited thereto. The buffer layer BL, the first gate insulator GI, the first interlayer dielectric layer IL1, and the second interlayer dielectric layer IL2 may be made up of a single inorganic layer including the above-described insulating material. In addition, in some embodiments, the first interlayer dielectric layer IL1 and the second interlayer dielectric layer IL2 may be made of an organic insulating material such as polyimide (PI).

The second conductive layer, the third conductive layer, and the fourth conductive layer may be made up of a single layer or multiple layers of one of molybdenum (Mo), aluminum (Al), chromium (Cr), gold (Au), titanium (T1), nickel (Ni), neodymium (Nd), and copper (Cu), or an alloy thereof. It is, however, to be understood that the present disclosure is not limited thereto.

A via layer VIA is located on the fourth conductive layer. The via layer VIA may include an organic insulating material (e.g., an organic insulating layer material such as polyimide (PI)) to provide a flat surface.

A plurality of electrodes RME: RME1 and RME2, a plurality of first banks BNL1, a second bank BNL2, a plurality of light-emitting diodes ED, and a plurality of contact electrodes CNE: CNE1 and CNE2 are located on the via layer VIA as the display elements layer. In addition, a plurality of passivation layers PAS1 and PAS2 may be located on the via layer VIA.

The first banks BNL1 may be located directly on the via layer VIA. The first banks BNL1 may extend in the first direction DR1 in the emission area EMA and may be spaced apart from each other in the second direction DR2. For example, one first bank BNL1 may be located on the left side of the center of the emission area EMA, and another first bank BNL1 may be located on the right side of the center of the emission area EMA.

The first banks BNL1 may have a shape extended in the first direction DR1, and may have a length that is less than the length of the area surrounded by the second bank BNL2 in the first direction DR1. That is to say, the first banks BNL1 may be located in the emission area EMA of each of the sub-pixels PXn to form an island-like pattern that has a relatively narrow width and that extends in one direction on the front surface of the display area DPA. Although the first banks BNL1 have the same width in the drawings, the present disclosure is not limited thereto. The first banks BNL1 may have different widths in other embodiments.

The first banks BNL1 may have a structure that at least partly protrudes from the upper surface of the via layer VIA. The protrusions of the first banks BNL1 may have inclined side surfaces. The light emitted from the light-emitting diodes ED may be reflected by the electrodes RME located on the first banks BNL1 so that the light may exit toward the upper side of, or away from, the via layer VIA. It is, however, to be understood that the present disclosure is not limited thereto. The first banks BNL1 may have a shape of a semi-circle or semi-ellipse having a curved outer surface. The first bank BNL1 may include, but is not limited to, an organic insulating material such as polyimide (PI).

The plurality of electrodes RME have a shape extended in one direction, and are located in each of the sub-pixels PXn. The plurality of electrodes RME may have a shape extended in the first direction DR1, and may be spaced apart from each other in the second direction DR2 in each of the sub-pixels PXn. The electrodes RME may be located across the emission area EMA and the second bank BNL2 in each sub-pixel PXn. The electrodes RME of one of the sub-pixels PXn may be spaced apart from the electrodes RME of another, adjacent one of the sub-pixels PXn in the first direction DR1 at a boundary thereof.

The plurality of electrodes RME may be used to generate an electric field in the sub-pixel PXn to align the light-emitting diodes ED during the process of fabricating the display device 10. The light-emitting diodes ED may receive a dielectrophoretic force by the electric field generated over the electrode RME, and may be aligned thereon.

According to some embodiments of the present disclosure, the display device 10 may include a first electrode RME1 and a second electrode RME2 located on each of the sub-pixels PXn. The first electrode RME1 and the second electrode RME2 may extend in the first direction DR1 on the via layer VIA and may be spaced apart from each other in the second direction DR2. The first electrode RME1 and the second electrode RME2 may have the same width, but the present disclosure is not limited thereto.

The first electrode RME1 may be located on the first bank BNL1 located on the left side of the emission area EMA. The second electrode RME2 may be spaced apart from the first electrode RME1 in the second direction DR2, and may be located on the first bank BNL1 located on the right side of the emission area EMA.

According to some embodiments of the present disclosure, the width of the plurality of electrodes RME measured in the second direction DR2 may be larger than that of the first bank BNL1. The first electrode RME1 and the second electrode RME2 may be located to cover both side surfaces of the first bank BNL1. The electrodes RME may be located to cover at least side surfaces of the first banks BNL1 that face each other, to reflect light emitted from the light-emitting diodes ED. The distance between the electrodes RME spaced apart in the second direction DR2 may be less than the distance between the first banks BNL1. At least a part of each of the electrodes RME may be located directly on the via layer VIA so that they may be located on the same plane.

Each of the first electrode RME1 and the second electrode RME2 may be connected to the fourth conductive layer thereunder. The first electrode RME1 and the second electrode RME2 may be connected directly to the fourth conductive layer through a first electrode contact hole CTD and a second electrode contact hole CTS, respectively, which are formed at such locations that they overlap with the second bank BNL2. For example, the first electrode RME1 may be in contact with the first conductive pattern CDP through the first electrode contact hole CTD penetrating the via layer VIA thereunder. The second electrode RME2 may be in contact with the second voltage line VL2 through the second contact hole CTS penetrating through the via layer VIA thereunder. The first electrode RME1 may be electrically connected to the first transistor T1 through the first conductive pattern CDP to receive the first supply voltage. The second electrode 22 may be electrically connected to the second voltage line VL2 to receive the second supply voltage. Because the first electrode RME1 and the second electrode RME2 are located separately in each of the sub-pixels PXn, the light-emitting diodes ED of different sub-pixels PXn may emit light individually.

The plurality of electrodes RME may be electrically connected to the light-emitting diodes ED. The electrodes RME may be connected to the light-emitting diodes ED through the contact electrodes CNE: CNE1 and CNE2 to be described below, and may transmit one or more electric signals applied from the fourth conductive layer to the light-emitting diodes ED. Electrical signals for allowing light-emitting diodes ED to emit light may be directly applied to the electrodes RME. In some embodiments where electrodes other than the first electrode RME1 and the second electrode RME2 are further included, the electric signals may be transmitted to the other electrodes through the contact electrodes CNE and light-emitting diodes ED.

Each of the electrodes RME may include a conductive material having a high reflectance. For example, the electrodes RME may include a metal such as silver (Ag), copper (Cu), and aluminum (Al) as the material having a high reflectance, and may be an alloy including aluminum (Al), nickel (Ni), lanthanum (La), etc. The electrodes RME may reflect light that is emitted from the light-emitting diodes ED, and that travels toward the side surfaces of the second bank BNL2, toward the upper side of each of the sub-pixels PXn.

It is, however, to be understood that the present disclosure is not limited thereto. The electrodes RME may further include a transparent conductive material. For example, each of the electrodes RME may include a material such as ITO, IZO, and ITZO. In some embodiments, each of the electrodes RME1 and RME2 may have a structure in which one or more layers of a transparent conductive material and one or more metal layers having high reflectivity are stacked on one another, or may be made up of a single layer including them. For example, each of the electrodes RME may have a stack structure such as ITO/Ag/ITO/, ITO/Ag/IZO, or ITO/Ag/ITZO/IZO.

The first insulating layer PAS1 is located on the via layer VIA and the plurality of electrodes RME. The first insulating layer PAS1 may be located to cover the electrodes RME entirely or partially, and may protect the plurality of electrodes RME and may insulate them from one another. In addition, the first insulating layer PAS1 also may reduce or prevent the likelihood that the light-emitting diodes ED located thereon are brought into contact with other elements to be damaged.

In some embodiments, the first insulating layer PAS1 may have steps so that a part of the upper surface thereof is recessed between the electrodes RME spaced apart from one another in the second direction DR2. The light-emitting diodes ED may be located at or near the steps of/a lower portion of the upper surface of the first insulating layer PAS1, and a space may be formed between the light-emitting diodes ED and the first insulating layer PAS1. It is, however, to be understood that the present disclosure is not limited thereto.

The first insulating layer PAS1 may be located to expose a part of the upper surface of each of the electrodes RME. The contact electrodes CNE to be described below may be in contact with the electrodes RME through parts of the electrode RME exposed by the first insulating layer PAS1.

The second bank BNL2 may be located on the first insulating layer PAS1.

The second bank BNL2 may be located in a lattice pattern including parts extended in the first direction DR1 and the second direction DR2 when viewed from the top, and may be located at the boundaries of the sub-pixels PXn to distinguish the adjacent sub-pixels PXn from each other.

The second bank BNL2 may have a height (e.g., a predetermined height). In some embodiments, the upper surface of the second bank BNL2 may be higher than that of the first bank BNL1, and the thickness of the second bank BNL2 may be equal to or greater than that of the first bank BNL1. The second bank BNL2 may reduce or prevent overflow of an ink into adjacent sub-pixels PXn during an inkjet printing process of the process of fabricating the display device 10. The second bank BNL2 may separate the different sub-pixels PXn from one another so that the ink in which different light-emitting diodes ED are dispersed are not mixed.

The light-emitting diodes ED may be located on the first insulating layer PAS1. The light-emitting diodes ED may include multiple layers located on the upper surface of the first substrate SUB1 in the direction parallel to it. The light-emitting elements 30 of the display device 10 may be arranged such that they extend in parallel to the first substrate SUB1. The multiple semiconductor layers included in the light-emitting elements 30 may be located sequentially in the direction parallel to the upper surface of the first substrate SUB1. It is, however, to be understood that the present disclosure is not limited thereto. In some implementations, when the light-emitting diodes ED have a different structure, a plurality of layers may be located in a direction perpendicular to the first substrate SUB1.

The plurality of light-emitting diodes ED may be spaced apart from one another in the first direction DR1 in which the electrodes RME extend, and may be aligned to be substantially parallel to one another. The light-emitting elements ED may have a shape extended in one direction. The direction in which the electrodes RME extend may be substantially perpendicular to the direction in which the light-emitting diodes ED extend. It is, however, to be understood that the present disclosure is not limited thereto. The light-emitting diodes ED may be oriented obliquely to the direction in which the electrodes RME extend.

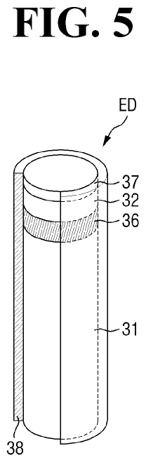

The light-emitting diodes ED may include a plurality of semiconductor layers, and may be in contact with the contact electrodes CNE1 and CNE2 to be described later. As a part of the semiconductor layer of each of the light-emitting diodes ED is exposed, because an insulating film 38 (see FIG. 5) of a light-emitting diode is not formed at the end surface on the side of the extending direction, the exposed part of the semiconductor layer may be in contact with the contact electrode CNE. In addition, in the display device 10 according to some embodiments, a part of the insulating film 38 located on the side surface of the light-emitting diode ED may be removed, and a part of the contact electrodes CNE may be connected to the side surface of the light-emitting diode ED. Each of the light-emitting diodes ED may be electrically connected to the first electrode RME1 or the conductive layers under the via layer VIA through the contact electrodes CNE, and an electric signal may be applied to each light-emitting diode ED so that light of a corresponding wavelength range may be emitted therefrom.

The light-emitting diodes ED located in each of the sub-pixels PXn may emit light of different wavelength ranges depending on the material of the semiconductor layer. It is, however, to be understood that the present disclosure is not limited thereto. The light-emitting diodes ED located in the sub-pixels PXn may emit light of the same color. The light-emitting diodes ED may include semiconductor layers doped with impurities of different conductivity types, and may be aligned so that their ends are directed in a corresponding orientation depending on the electric field generated over the electrodes RME.

The length of the light-emitting diodes ED may be greater than the distance between the first electrode RME1 and the second electrode RME2, and the two ends of the light-emitting elements ED may be located on the first electrode RME1 and the second electrode RME2, respectively. Each of the light-emitting diodes ED may include a plurality of semiconductor layers, and a first end, and a second end opposite to the first end, may be defined with respect to one of the semiconductor layers. Each of the light-emitting diodes ED may be located such that the first end and the second end are placed on the first electrode RME1 and the second electrode RME2, respectively. It is, however, to be understood that the present disclosure is not limited thereto. Some of the plurality of light-emitting diodes ED may be located such that only one of the ends is placed on the respective one of the electrodes RME1 and RME2 depending on the orientations between the first electrode RME1 and the second electrode RME2.

The second insulating layer PAS2 may be located on the first insulating layer PAS1 and the light-emitting diodes ED. In addition, the second insulating layer PAS2 may be located on the exposed parts of the electrodes RME1 and RME2 on which the first insulating layer PAS1 is not located, and may be located to partially overlap the electrodes RME1 and RME2. For example, the second insulating layer PAS2 may include a pattern portion PT partially surrounding the outer surface of each of the light-emitting diode ED. The pattern portion PT of the second insulating layer PAS2 may be located so that it does not cover the first end and the second end of the light-emitting diode ED, and may extend on the first insulating layer PAS1 in the first direction DR1, and may form a linear or island pattern within each of the sub-pixels PXn when viewed from the top. The pattern portion PT of the second insulating layer PAS2 may protect the light-emitting diode ED, and may fix the light-emitting diode ED during the process of fabricating the display device 10. In addition, in some embodiments, a part of the pattern portion PT may be located to fill the space between light-emitting diode ED and the first insulating layer PAS1 thereunder.

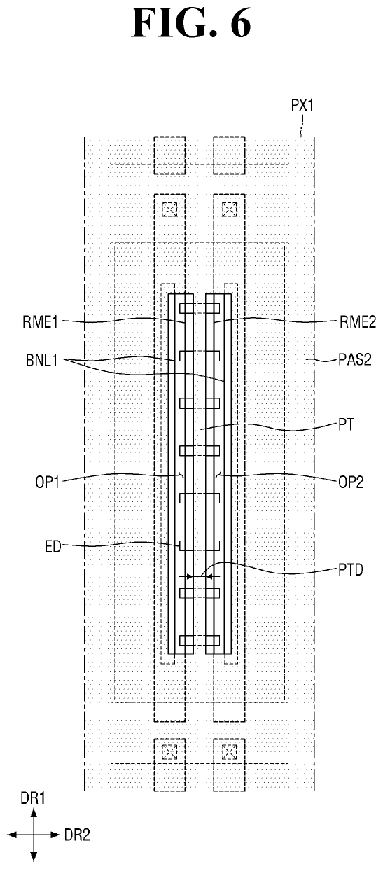

The second insulating layer PAS2 may be located entirely on the first insulating layer PAS1 while exposing both ends of the light-emitting diode ED so that the pattern portion PT is formed. According to some embodiments of the present disclosure, the second insulating layer PAS2 may include openings OP1 and OP2 (see FIG. 6) for exposing both ends of the light-emitting diode ED, respectively. The openings OP1 and OP2 are formed to overlap parts of the electrodes RME1 and RME2, respectively, so that the overlapped parts are exposed. The exposed parts may be connected to the contact electrodes CNE1 and CNE2, respectively. In addition, the second insulating layer PAS2 may be located also on the second bank BNL2. The second insulating layer PAS2 may be shaped to be formed entirely on the first insulating layer PAS1 during the process of fabricating the display device 10, and then may be removed during the process of exposing both ends of the light-emitting diodes ED.

According to some embodiments of the present disclosure, the second insulating layer PAS2 may transmit light having a wavelength that lies within the wavelength range of the light emitted from the light-emitting diode ED while blocking other lights having a wavelength that is outside of the wavelength range of the light emitted from the light-emitting diode ED. The second insulating layer PAS2 may cover and affix the light-emitting diode ED, and may transmit light emitted from the light-emitting diode ED so that light exits from each of the sub-pixels PXn. However, some lights may be blocked from exiting from the sub-pixels PXn. For example, a plurality of electrodes RME1 and RME2 including a material having a high reflectivity may be located in each of the sub-pixels PXn of the display device 10, and the second insulating layer PAS2 may reduce or prevent some of the lights reflected by the electrodes RME1 and RME2 from exiting from the sub-pixels PXn. The second insulating layer PAS2 may have a thickness sufficient to fix the light-emitting diodes ED while transmitting the light emitted from the light-emitting diodes ED smoothly, and while blocking the transmission of the light reflected off the electrodes RME1 and RME2. In some embodiments, the second insulating layer PAS2 may have a thickness from about 0.1 μm to about 1.0 μm. The arrangement of the second insulating layer PAS2 and ability for blocking light will be described later with reference to other drawings.

The plurality of contact electrodes CNE may be located on the light-emitting diodes ED and the second insulating layer PAS2. Each of the contact electrodes CNE may be located on a respective one of the electrodes RME1 and RME2 to be in contact with a respective end of the light-emitting diode ED and one of the electrodes RME. For example, the contact electrodes CNE may be in contact with the ends of the light-emitting diode ED exposed by the openings OP1 and OP2 of the second insulating layer PAS2, and in contact with an exposed part of the electrodes RME on which the first insulating layer PAS1 is not located.

The plurality of contact electrodes CNE may extend in the first direction DR1 and may be located in the emission area EMA. The first contact electrode CNE1 may be located on the first electrode RME1 and may extend in the first direction DR1, and the second contact electrode CNE2 may be located on the second electrode RME2 and may extend in the first direction DR1. In addition, the first contact electrode CNE1 and the second contact electrode CNE2 may be spaced apart from each other in the second direction DR2 by the pattern portion PT of the second insulating layer PAS2. The first contact electrode CNE1 may be in contact with the first electrode RME1 and the first end of the light-emitting diode ED, and the second contact electrode CNE2 may be in contact with the second electrode RME2 and the second end of the light-emitting diode ED. The light-emitting diodes ED may receive the electric signal applied to the electrodes RME through the first contact electrode CNE1 and the second contact electrode CNE2 to emit light of a corresponding wavelength range.

Although the contact electrodes CNE are located directly on the light-emitting diode ED, and are formed as substantially the same layer on the second insulating layer PAS2, as shown in the drawings, the present disclosure is not limited thereto. In some embodiments, one or more additional insulating layers may be further located between the contact electrodes CNE, and thus the contact electrodes CNE may be located on different layers.

The contact electrodes CNE may include a conductive material. For example, the contact electrodes may include ITO, IZO, ITZO, aluminum (Al), etc. For example, the contact electrodes CNE may include a transparent conductive material, and light emitted from the light-emitting diodes ED may transmit through the contact electrodes CNE to proceed toward the electrodes RME. It is, however, to be understood that the present disclosure is not limited thereto.

In some embodiments, an insulating layer may be further located on the contact electrodes CNE to cover them. The insulating layer may be located entirely on, or to cover an entirety of, the first substrate SUB1 to protect the elements located on the first substrate SUB1 against the external environment.

FIG. 5 is a view showing a light-emitting element according to some embodiments of the present disclosure.

Referring to FIG. 5, a light-emitting element ED may be a light-emitting diode. For example, the light-emitting element ED may have a size from nanometers to micrometers, and may be an inorganic light-emitting diode made of an inorganic material. The light-emitting diode ED may be aligned between two electrodes facing each other as polarities are created by forming an electric field in a corresponding direction between the two electrodes.

The light-emitting diode ED according to some embodiments may have a shape extended in one direction. The light-emitting element ED may have a shape of a cylinder, a rod, a wire, a tube, etc. It is to be understood that the shape of the light-emitting diode ED is not limited thereto. The light-emitting diode ED may have a variety of shapes including a polygonal column shape such as a cube, a cuboid, and a hexagonal column, or a shape that extends in a direction with partially inclined outer surfaces.

The light-emitting diode ED may include semiconductor layers doped with impurities of a conductive type (e.g., p-type or n-type). The semiconductor layers may emit light of a certain wavelength range by transmitting an electric signal applied from an external power source. The light-emitting diode ED may include a first semiconductor layer 31, a second semiconductor layer 32, a third semiconductor layer 33, an emissive layer 36, an electrode layer 37, and an insulating film 38.

The first semiconductor layer 31 may be an n-type semiconductor. The first semiconductor layer 31 may include a semiconductor material having the following chemical formula: AlₓGa_{y}In_{1-x-y}N (0≤x≤1, 0≤y≤1, 0≤x+y≤1). For example, the first semiconductor layer 31 may be one or more of n-type doped AlGaInN, GaN, AlGaN, InGaN, AlN and InN. The n-type dopant doped into the first semiconductor layer 31 may be Si, Ge, Sn, etc.

The second semiconductor layer 32 is located above the first semiconductor layer 31 with the emissive layer 36 therebetween. The second semiconductor layer 32 may be a p-type semiconductor, and may include a semiconductor material having the following chemical formula: AlₓGa_{y}In_{1-x-y}N (0≤x≤1, 0≤y≤1, 0≤x+y≤1). For example, the second semiconductor layer 32 may be one or more of p-type doped AlGaInN, GaN, AlGaN, InGaN, AlN and InN. The p-type dopant doped into the second semiconductor layer 32 may be Mg, Zn, Ca, Se, Ba, etc.

Although each of the first semiconductor layer 31 and the second semiconductor layer 32 is implemented as a signal layer in the drawings, the present disclosure is not limited thereto. Depending on the material of the emissive layer 36, the first semiconductor layer 31 and the second semiconductor layer 32 may further include a greater number of layers (e.g., may include a clad layer and/or a tensile strain barrier reducing (TSBR) layer).

The emissive layer 36 is located between the first semiconductor layer 31 and the second semiconductor layer 32. The emissive layer 36 may include a material having a single or multiple quantum well structure. When the emissive layer 36 includes a material having the multiple quantum well structure, the structure may include quantum layers and well layers alternately stacked on one another. The emissive layer 36 may emit light as electron-hole pairs are combined therein in response to an electrical signal applied through the first semiconductor layer 31 and the second semiconductor layer 32. The emissive layer 36 may include a material such as AlGaN and AlGaInN. For example, when the emissive layer 36 has a multi-quantum well structure in which quantum layers and well layers are alternately stacked on one another, the quantum layers may include AlGaN or AlGaInN, and the well layers may include a material such as GaN and AlGaN.

The electrode layer 37 may be an ohmic contact electrode or a Schottky contact electrode. The light-emitting diode ED may include at least one electrode layer 37. The light-emitting diode ED may include one or more electrode layers 37. It is, however, to be understood that the present disclosure is not limited thereto. The electrode layer 37 may be eliminated.

The electrode layer 37 may reduce the resistance between the light-emitting element ED and the electrodes or the contact electrodes when the light-emitting element ED is electrically connected to the electrodes or the contact electrodes in the display device 10. The electrode layer 37 may include a metal having conductivity. For example, the electrode layer 37 may include at least one of aluminum (Al), titanium (T1), indium (In), gold (Au), silver (Ag), ITO, IZO, and ITZO.

The insulating film 38 is located to surround, or partially surround, the outer surfaces of the plurality of semiconductor layers and electrode layers described above. For example, the insulating film 38 may be located to surround at least the outer surface of the emissive layer 36, with both ends of the light-emitting element ED in the longitudinal direction being exposed. In addition, a part of the upper surface of the insulating film 38 may be rounded in cross section, which is adjacent to at least one of the ends of the light-emitting diode ED.

The insulating film 38 may include materials having insulating properties such as silicon oxide (SiOx), silicon nitride (SiNx), silicon oxynitride (SiOxNy), aluminum nitride (AlNx), and aluminum oxide (AlOx). Although the insulating film 38 is formed as a single layer in the drawings, the present disclosure is not limited thereto. In some embodiments, the insulating film 38 may be made up of a multilayer structure in which multiple layers are stacked on one another.

The insulating film 38 may serve to protect the above-described elements. The insulating film 38 may reduce or prevent the likelihood of an electrical short-circuit that may occur in the emissive layer 36 if the emissive layer 36 comes in direct contact with an electrode through which an electric signal is transmitted to the light-emitting diode ED. In addition, the insulating film 38 may reduce or prevent a decrease in luminous efficiency.

In addition, the outer surface of the insulating film 38 may be subjected to surface treatment. The light-emitting diodes ED may be dispersed in an ink, and the ink may be sprayed onto the electrode. In doing so, a surface treatment may be applied to the insulating film 38 so that it becomes hydrophobic or hydrophilic to thereby keep the light-emitting diodes ED dispersed in the ink from being aggregated with one another.

In the sub-pixel PXn of the display device 10, lights incident from the outside may be reflected at the electrodes RME1 and RME2, and may exit together with the lights emitted from the light-emitting diodes ED. In this regard, the display device 10 according to some embodiments includes the second insulating layer PAS2 located on the light-emitting diodes ED and the electrodes RME1 and RME2 to transmit only light of a corresponding wavelength range, so that lights from the light-emitting diodes ED may exit while reflection of external light by the electrodes RME1 and RME2 may be reduced.

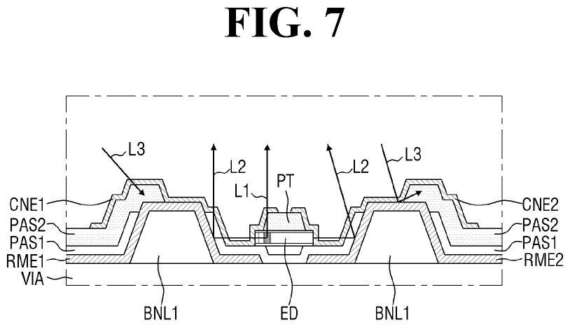

FIG. 6 is a plan view showing a layout of a second insulating layer in a display device according to some embodiments of the present disclosure, and FIG. 7 is a cross-sectional view schematically showing paths of light in a display device according to some embodiments. FIG. 6 schematically shows the relative arrangement of the electrodes RME1 and RME2, the light-emitting diodes ED, and the second insulating layer PAS2 in a sub-pixel PXn. FIG. 7 shows the paths of lights L1 and L2 emitted from the light-emitting diode ED, and the path of light L3 incident from the outside.

Referring to FIGS. 6 and 7, in connection with FIG. 4, the second insulating layer PAS2 may be located entirely in the display area DPA of the display device 10. The second insulating layer PAS2 may be located in the emission area EMA and the non-emission area of the sub-pixel PXn, and may be located on the first insulating layer PAS1, the light-emitting diode ED, the electrodes RME1 and RME2, and the second bank BNL2 in the cross-sectional view.

According to some embodiments of the present disclosure, the second insulating layer PAS2 may include a plurality of openings OP1 and OP2 exposing the ends of the light-emitting diodes ED and extending in the first direction DR1, and may also include a pattern portion PT located on the light-emitting diodes ED and extended in the first direction DR1. The first opening OP1 may expose first ends of the light-emitting diodes ED, and may be located to overlap the first electrode RME1 and one of the first banks BNL1. In the first opening OP1, a part of the first electrode RME1 that is exposed at an area at which the first insulating layer PAS1 is not located, and a part of the first insulating layer PAS1, may be exposed. The second opening OP2 may expose second ends of the light-emitting diodes ED, and may be located to overlap the second electrode RME2 and another one of the first banks BNL1. In the second opening OP2, a part of the second electrode RME2 that is exposed at an area at which the first insulating layer PAS1 is not located, and a part of the first insulating layer PAS1, may be exposed. The parts of the electrodes RME1 and RME2, which are exposed via the openings OP1 and OP2 of the second insulating layer PAS2 and via omitted portions of the first insulating layer PAS1, may be in contact with the contact electrodes CNE1 and CNE2, respectively.

The pattern portion PT may be located between the first opening OP1 and the second opening OP2, and may be located on the plurality of light-emitting diodes ED arranged in the first direction DR1. Each of the first opening OP1, the second opening OP2, and the pattern portion PT may have a shape extended in the first direction DR1 along which the light-emitting diodes ED are arranged. In addition, the pattern portion PT may have a width PTD such that the both ends of the light-emitting diodes ED may be exposed. According to some embodiments of the present disclosure, the width PTD of the pattern portion PT measured in the second direction DR2 may be less than the length of the light-emitting diodes ED. For example, the width PTD of the pattern portion PT may have a range of about 3 μm or less.

In addition, the contact electrodes CNE may be spaced apart from each other in the second direction DR2 on the pattern portion PT of the second insulating layer PAS2. The pattern portion PT may be located between the first opening OP1 and the second opening OP2, and may extend in the first direction DR1 along which the plurality of light-emitting diodes ED is arranged. The pattern portion PT may be connected to the other part of the second insulating layer PAS2 that excludes the openings OP1 and OP2. For example, the pattern portion PT may be connected to the part of the second insulating layer PAS2 that is located where the light-emitting diodes ED are not located in the second bank BNL2 and in the emission area EMA. The other part of the second insulating layer PAS2 that excludes the openings OP1 and OP2 may be directly located on, and in direct contact with, the upper surfaces of the exposed electrodes RME1 and RME2 because the first insulating layer PAS1 is not located.

As mentioned earlier, the second insulating layer PAS2 may transmit light in a corresponding wavelength range while blocking light in other wavelength ranges. The second insulating layer PAS2 may include a colorant, such as a dye and a pigment that absorbs lights in wavelength ranges that are other than a corresponding wavelength range. For example, the second insulating layer PAS2 may transmit light having a center wavelength range that is similar to that of the light emitted from the light-emitting diodes ED while blocking transmission of light having other center wavelength ranges. According to some embodiments of the present disclosure, the display device 10 may include a light-emitting diode ED that emits blue light of the third color, and the second insulating layer PAS2 may transmit light having a center wavelength range from about 400 nm to about 500 nm while blocking the transmission of the other lights.

The wavelength ranges of the light emitted from the light-emitting diodes ED and the light transmitting through the second insulating layer PAS2 may partially overlap each other. For example, the second insulating layer PAS2 may transmit lights having the same central wavelength range as the light emitted from the light-emitting diodes ED, or may transmit the lights having a wavelength range within the full width at half maximum (FWHM) of the light emitted from the light-emitting diodes ED. That is to say, the second insulating layer PAS2 may selectively transmit lights having a wavelength within the spectrum that the light emitted from the light-emitting diodes ED has, including the lights having the wavelength falling in the center wavelength range of the light emitted from the light-emitting diodes ED.

The light may exit from the emissive layer 36 of the light-emitting diode ED without directivity. First light L1 may be generated in the emissive layer 36 of the light-emitting diode ED and may exit through the side surface of the light-emitting diode ED. The second insulating layer PAS2 may transmit the first light L1 emitted from the light-emitting diode ED, and the first light L1 may pass through the insulating film 38 and the second insulating layer PAS2 to exit toward the upper surface of the first substrate SUB1 or the via layer VIA. In addition, second light L2 may be generated in the emissive layer 36 of the light-emitting diode ED and may exit through both end surfaces of the light-emitting diode ED. The second light L2 may travel toward the inclined side surfaces of the first banks BNL1, and may be reflected off of the electrodes RME1 and RME2 located on the first banks BNL1 to exit toward the upper surface of the first substrate SUB1 or the via layer VIA.

Incidentally, the third light L3 may be incident on the display device 10 from the outside, other than the lights L1 and L2 generated in the light-emitting diode ED. The third light L3 may be directed toward the upper surface of the first substrate SUB1 at each of the sub-pixels PXn, and a part of the third light L3 may be reflected at the electrodes RME1 and RME2 or at the conductive layer located in the circuit layer CCL thereunder. The reflected third lights L3 (hereinafter referred to as reflected light) may exit to the outside of the display device 10 again, which may deteriorate visibility of the user watching display device 10. The display device 10 according to some embodiments of the present disclosure may include the second insulating layer PAS2 that blocks the transmission of light in a corresponding wavelength range, so that it is possible to reduce the amount of light that is incident from the outside and that is reflected by the electrodes RME1 and RME2 or another conductive layer, such as the third light L3. A layer that may reflect the third light L3 incident from the outside (e.g., the electrodes RME1 and RME2 and the conductive layers of the circuit layer CCL) may be between the second insulating layer PAS2 and the first substrate SUB1. Some of the reflected lights may be incident on the second insulating layer PAS2. Among the reflected lights incident on the second insulating layer PAS2, the lights having a central wavelength range that is different from that of the lights L1 and L2 emitted from the light-emitting diode ED may be blocked or absorbed by the second insulating layer PAS2. In addition, among the third lights L3, light directly incident on the second insulating layer PAS2 may also be blocked or absorbed by the second insulating layer PAS2.

According to some embodiments, the area of the second insulating layer PAS2 per unit area of each of the sub-pixels PXn of the display device 10 may be about 80% or more. The second insulating layer PAS2 may be located across the emission area EMA and the sub-area SA. The area occupied by the other parts of the second insulating layer PAS2 (e.g., other than the openings OP1 and OP2) per unit area of each of the sub-pixels PXn may be equal to or greater than about 80%. For example, the second insulating layer PAS2 may be located to overlap the plurality of electrodes RME1 and RME2 and the conductive layer of the circuit layer CCL thereunder in the thickness direction. The display device 10 may transmit lights emitted from the light-emitting diodes ED while blocking the transmission of some of other lights to thereby reduce the reflection of external light, and thus the visibility may be improved.

Hereinafter, display devices according to a variety of embodiments of the present disclosure will be described with reference to other drawings.

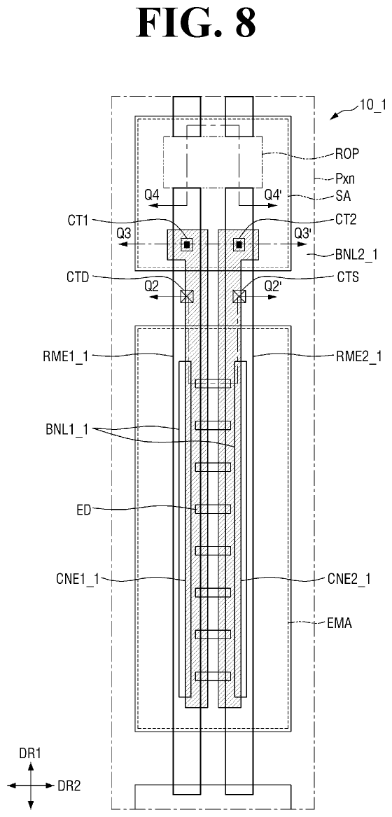

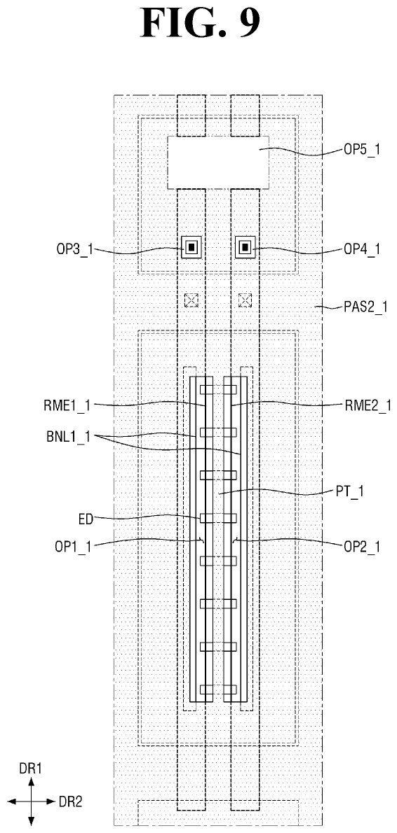

FIG. 8 is a plan view showing a sub-pixel of a display device according to other embodiments of the present disclosure, and FIG. 9 is a plan view schematically showing arrangement of a second insulating layer in the display device of FIG. 8. FIG. 9 schematically shows the relative arrangement of the electrodes RME1 and RME2, the light-emitting diodes ED, and the second insulating layer PAS2 in a single sub-pixel PXn.

Referring to FIGS. 8 and 9, each of sub-pixels PXn of a display device 10_1 according to some embodiments may further include a sub-area SA located in a non-emission area. The sub-area SA may be located on a side of the emission area EMA in the first direction DR1, and may be located between the emission areas EMA of adjacent ones of the sub-pixels PXn that are adjacent to each other in the first direction DR1. For example, the plurality of emission areas EMA and the sub-areas SA may be arranged repeatedly in the second direction DR2, and may be arranged alternately in the first direction DR1. A second bank BNL2 may be located between the sub-areas SA and the emission areas EMA, and the distance between them may vary depending on the width of the second bank BNL2. No light-emitting diode ED is located in the sub-areas SA and thus no light exits therefrom. The electrodes RME located in the sub-pixels PXn may be partially located in the sub-areas SA. The electrodes RME located in different sub-pixels PXn may be located separately from one another, or separated from each other, in the sub-area SA.

In some embodiments in which each of the sub-pixels PXn includes the emission area EMA and the sub-area SA, a plurality of electrodes RME1_1 and RME2_1 may extend in the first direction DR1, and may be located across the emission area EMA and the sub-area SA. The electrodes RME1_1 and RME2_1 of the sub-pixel PXn may be separated from those of another, adjacent sub-pixel PXn, which is adjacent to the sub-pixel PXn in the first direction DR1, at a separation region ROP of the sub-area SA. The plurality of electrodes RME1_1 and RME2_1 may be formed as an electrode line extended in the first direction DR1 during the process of fabricating the display device 10, and may be used in the process of aligning the light-emitting diodes ED. The electrode line may be separated into parts at the separation region ROP to form the electrodes RME1_1 and RME2_1 located in each of the sub-pixels PXn.

Although each of the electrodes RME1_1 and RME2_1 is separated into parts at the separation region ROP of the sub-area SA in the drawings, the present disclosure is not limited thereto. In some embodiments, the electrodes RME located in each of the sub-pixels PXn may be spaced apart from each other in a separation portion ROP formed in the emission area EMA. In this instance, the plurality of electrodes RME1_1 and RME2_1 may be sorted into an electrode group located on one side of the separation region ROP of the emission area EMA, and another electrode group located on the opposite side of the separation region ROP.

According to some embodiments in which the display device 10_1 further includes the sub-area SA, parts of the upper surfaces of the electrodes RME1_1 and RME2_1 exposed by the first insulating layer PAS1 might not be located in the second direction DR2 of the light-emitting diodes ED. In other words, the exposed parts of the upper surfaces of the electrodes RME1_1 and RME2_1 may be spaced apart from the positions where the light-emitting diodes ED are located in the first direction DR1. In the display device 10_1 according to some embodiments, the first insulating layer PAS1 may be located to cover the upper surfaces of the electrodes RME1_1 and RME2_1 in the emission area EMA, and contacts CT1 and CT2, which correspond to contact openings described further below, may be formed in the sub-area SA to expose parts of the upper surfaces of the electrodes RME1_1 and RME2_1.

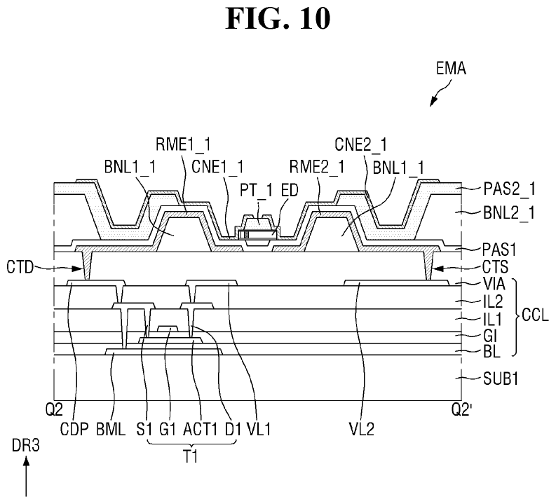

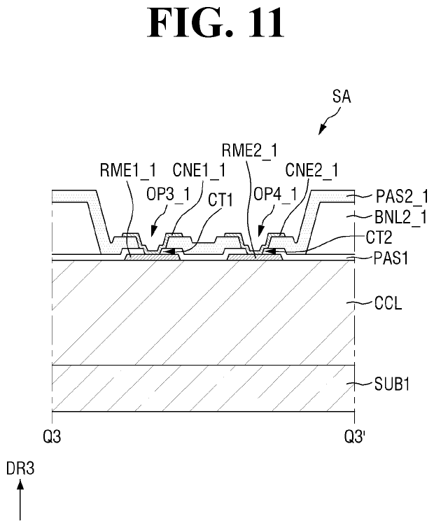

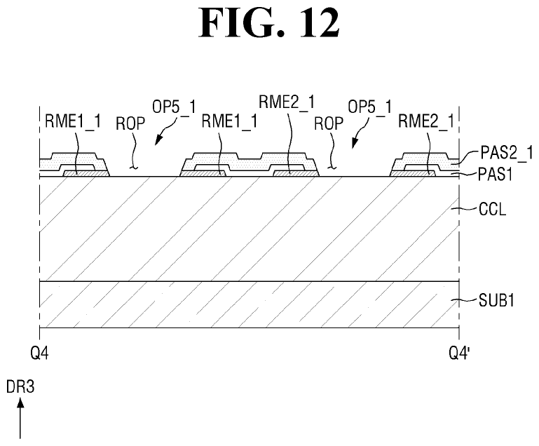

FIG. 10 is a cross-sectional view taken along the line Q2-Q2′ of FIG. 8, FIG. 11 is a cross-sectional view taken along the line Q3-Q3′ of FIG. 8, and FIG. 12 is a cross-sectional view taken along the line Q4-Q4′ of FIG. 8. FIG. 10 shows a cross section passing through both ends of the light-emitting diode ED located in the emission area EMA, and FIG. 11 shows a cross section passing through a plurality of contacts CT1 and CT2. FIG. 12 shows the electrodes RME1_1 and RME2_1 spaced apart from each other at a separation region ROP of the sub-area SA.

Referring to FIGS. 10 to 12, in conjunction with FIGS. 8 and 9, the plurality of electrodes RME1_1 and RME2_1 may be located across the emission area EMA and the sub-area SA, while a plurality of light-emitting diodes ED may be located only in the emission area EMA. In the portion of the emission area EMA where the light-emitting diodes ED are located, the first insulating layer PAS1_1 may be located to cover all of the plurality of electrodes RME1_1 and RME2_1. Unlike the embodiments of FIG. 4, parts of the second insulating layer PAS2_1 overlapping the electrodes RME1_1 and RME2_1 might not be in direct contact with the electrodes RME1_1 and RME2_1, but instead may be located on the first insulating layer PAS1_1.

A plurality of contact electrodes CNE1_1 and CNE2_1 may be located across the emission area EMA and the sub-area SA. The contact electrodes CNE1_1 and CNE2_1 may be in contact with at least one of the electrodes RME1_1 and RME2_1 through the contacts CT1 and CT2 of the first insulating layer PAS1_1 (e.g., respectively), which are formed in the sub-area SA and which expose parts of the upper surfaces of the electrodes RME1_1 and RME2_1. The parts of the contact electrodes CNE1_1 and CNE2_1 located in the emission area EMA may be in contact with the light-emitting diodes ED. The parts of the contact electrodes CNE1_1 and CNE2_2 located in the sub-area SA may be in contact with the electrodes RME1_1 and RME2_1 through the contacts CT1 and CT2. The contact electrodes CNE1_1 and CNE2_1 may be partially located on the second bank BNL2 that is located between the emission area EMA and the sub-area SA.

The first contact electrode CNE1_1 and the second contact electrode CNE2_1 may be located on the first electrode RME1_1 and the second electrode RME2_1, respectively. Each of the first contact electrode CNE1_1 and the second contact electrode CNE2_1 may extend in the first direction DR1, and may form a linear pattern in the emission area EMA of each of the sub-pixels PXn. The first contact electrode CNE1_1 may be in contact with the first electrode RME1_1 through the first contact CT1 exposing the upper surface of the first electrode RME1_1 in the sub-area SA, and the second contact electrode CNE2_1 may be in contact with the second electrode RME2_1 through the second contact CT2 exposing the upper surface of the second electrode RME2_1 in the sub-area SA.

The second insulating layer PAS2_1 may be partially located in the sub-area SA as well. The second insulating layer PAS2_1 may be located entirely in the emission area EMA and the sub-area SA in each of the sub-pixels PXn, and may further include a plurality of openings OP3_1, OP4_1, and OP5_1 located in the sub-area SA in addition to a first opening OP1_1 and a second opening OP2_1 located in the emission area EMA.

According to some embodiments of the present disclosure, the second insulating layer PAS2_1 may further include the third opening OP3_1 overlapping the first contact CT1, the fourth opening OP4_1 overlapping the second contact CT2, and the fifth opening OP5_1 overlapping the separation region ROP of the electrodes RME1_1 and RME2_1.

The third opening OP3_1 and the fourth opening OP4_1 may expose contacts CT1 and CT2 in the sub-area SA, respectively. The third opening OP3_1 and the fourth opening OP4_1 may expose the upper surfaces of the electrodes RME1_1 and RME2_1 together with the contacts CT1 and CT2. The contact electrodes CNE1_1 and CNE2_1 may be located on the second insulating layer PAS2_1 and may be in contact with the electrodes RME1_1 and RME2_1 through the third opening OP3_1 and the fourth opening OP4_1, respectively.

The plurality of electrodes RME1_1 and RME2_1 may be formed by separating the electrode lines into parts at the separation region ROP of the sub-area SA after aligning the light-emitting diodes ED and after forming the second insulating layer PAS2. The fifth opening OP5_1 of the second insulating layer PAS2_1 may be located to overlap the separation region ROP in the sub-area SA to expose the electrode lines in the process of separating the electrode lines. The electrode lines exposed by the fifth opening OP5_1 may be separated into parts at the separation region ROP, and the upper surface of the via layer VIA thereunder may be partially exposed in the fifth opening OP5_1. Accordingly, the first electrode RME1_1 and the second electrode RME2_1 may be spaced apart from the electrodes located in another sub-pixel PXn in the first direction DR1 at the separation region ROP and may be omitted from the fifth opening OP5_1.

In the display device 10_1 according to some embodiments, each of the sub-pixels PXn includes the emission area EMA and the sub-area SA, and the arrangement of the electrodes RME1_1 and RME2_1 and the contact electrodes CNE1_1 and CNE2_1 may be altered when viewed from the top. In accordance therewith, the second insulating layer PAS2_1 is entirely located in the emission area EMA and the sub-area SA to reduce reflection of external light. In addition, the second insulating layer PAS2_1 further includes the plurality of openings OP3_1, OP4_1, and OP5_1, so that the light-emitting diodes ED may be electrically connected to the electrodes RME1_1 and RME2_1 through the contact electrodes CNE1_1 and CNE2_1.

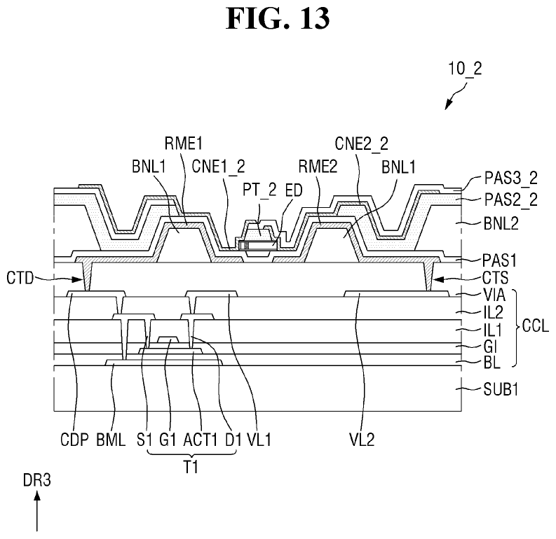

FIG. 13 is a cross-sectional view showing a part of a display device according to other embodiments of the present disclosure.

Referring to FIG. 13, in a the display device 10_2 according to some embodiments, a first contact electrode CNE1_2 and a second contact electrode CNE2_2 may be located on different layers, and a third insulating layer PAS3_2 may be further located therebetween. The present example is different from the embodiments of FIG. 4 in that the display device 10_2 includes more insulating layers.

The third insulating layer PAS3_2 may be located over the first insulating layer PAS1, the second insulating layer PAS2_2, and the second contact electrode CNE2_2. The third insulating layer PAS3_2 may be located entirely on the first insulating layer PAS1 and the second insulating layer PAS2_2, leaving one end of each of the light-emitting diodes ED on which the first contact electrode CNE1_2 is located. A part of the first contact electrode CNE1_2 may be located on the third insulating layer PAS3_2. The first contact electrode CNE1_2 and the second contact electrode CNE2_2 may be insulated from each other by the third insulating layer PAS3_2.

In the above-described embodiments, the first contact electrode CNE1 and the second contact electrode CNE2 may be formed via the same process. In contrast, in the display device 10_2 according to some embodiments, at least one insulating layer may be located between the contact electrodes CNE1_2 and CNE2_2, and accordingly the contact electrodes CNE1 and CNE2 may be formed via different processes. For example, once the second insulating layer PAS2_2 is formed after the light-emitting diodes ED are located, the second contact electrode CNE2_2 is formed first, and then the third insulating layer PAS3_2 and the first contact electrode CNE1_2 are formed. In the display device 10_2, the contact electrodes CNE1_2 and CNE2_2 may be insulated from each other by the third insulating layer PAS3_2, and thus it is possible to reduce or prevent the likelihood of a short circuit due to the residues of, or residual portions of, the contact electrode materials during the fabricating process.

Incidentally, the display device 10 may further include structures or layers that are located on the second bank BNL2 and the light-emitting diodes ED to control the color of light emitted from each of the sub-pixels PXn. Such structures and the layers may be located in certain locations in the emission area EMA in accordance with the shape of the electrodes RME and the arrangement of the light-emitting diodes ED of the display device 10.

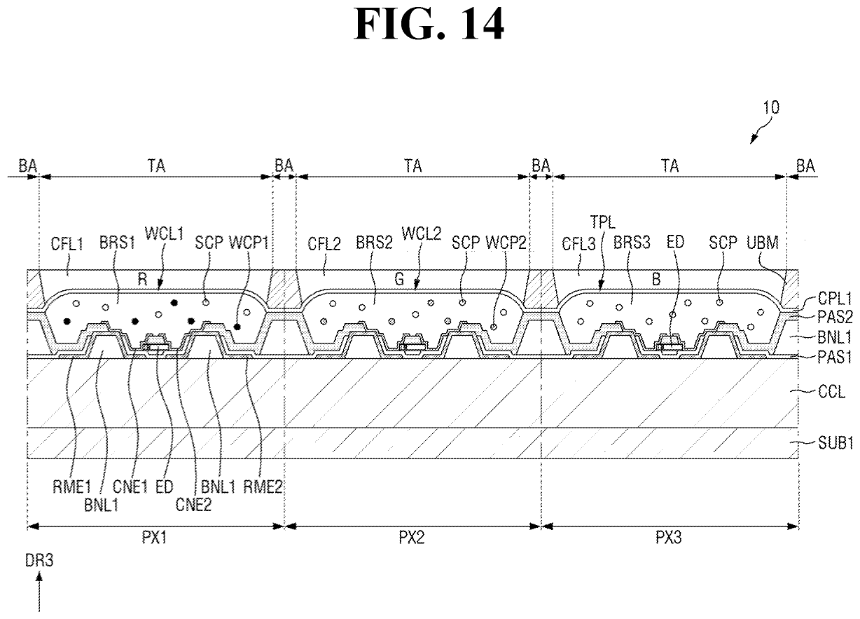

FIG. 14 is a cross-sectional view of a display device according to some embodiments of the present disclosure.

Referring to FIG. 14, a display device 10 according to some embodiments may further include color control structures TPL, WCL1, and WCL2 located over the light-emitting diodes ED, and a plurality of color filter layers CFL1, CFL2, and CFL3. The display device 10 may emit light of different colors even if the sub-pixels PXn include the same type of light-emitting diodes ED as it further includes the color control structures TPL, WCL1, and WCL2 and the color filter layers CFL1, CFL2, and CFL3.

The display device 10 may include a plurality of light-transmitting areas TA where the color filter layers CFL1, CFL2, and CFL3 are located to allow light to exit, and a light-blocking area BA between the light-transmitting areas TA where no light exits. The light-transmitting areas TA may be located in line with certain portions of the emission area EMA of each of the sub-pixels PXn, and the light-blocking area BA may be areas other than the light-transmitting areas TA. As will be described later, the light-transmitting areas TA and the light-blocking area BA may be distinguished by a first light-blocking member UBM.

The color control structures TPL, WCL1, and WCL2 may be located over the light-emitting diodes ED. The color control structures TPL, WCL1, and WCL2 may be located in an area surrounded by the second bank BNL2. However, the color control structures TPL, WCL1, and WCL2 may extend in the first direction DR1 and may be located beyond the second bank BNL2 when viewed from the top. The color control structures TPL, WCL1, and WCL2 may also be located on a part of the second bank BNL2 extended in the second direction DR2, in addition to the emission area EMA and the sub-area SA surrounded by the second bank BNL2, to form a linear pattern in the display area DPA. It is, however, to be understood that the present disclosure is not limited thereto. The color control structures TPL, WCL1, and WCL2 may be located only in the emission area EMA in which the light-emitting diodes ED are located to form an island-shaped pattern in the display area DPA.

In some embodiments where the light-emitting diodes ED of each of the sub-pixels PXn emit blue light of the third color, the color control structures TPL, WCL1, and WCL2 may include a first wavelength conversion layer WCL1 located in the first sub-pixel PX1, a second wavelength conversion layer WCL2 located in the second sub-pixel PX2, and a transparent layer TPL located in the third sub-pixel PX3.

The first wavelength conversion layer WCL1 may include a first base resin BRS1 and first wavelength-converting particles WCP1 dispersed in the first base resin BRS1. The second wavelength conversion layer WCL2 may include a second base resin BRS2 and second wavelength-converting particles WCP2 dispersed in the second base resin BRS2. The first wavelength conversion layer WCL1 and the second wavelength conversion layer WCL2 convert and transmit the wavelength of the blue light of the third color incident from the light-emitting diodes ED. The first wavelength conversion layer WCL1 and the second wavelength conversion layer WCL2 may further include scattering particles SCP included in each base resin, and the scattering particles SCP may increase wavelength conversion efficiency.

The transparent layer TPL may include a base resin BRS3 and scattering particles SCP dispersed in the third base resin BRS3. The transparent layer TPL transmits the wavelength of the blue light of the third color incident from the light-emitting diodes ED as it is. The scattering particles SCP of the transparent layer TPL may adjust paths of light exiting through the transparent layer TPL. The transparent layer TPL may include no wavelength conversion material.

The scattering particles SCP may be metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), etc. Examples of the material of the organic particles may include an acrylic resin, a urethane resin, etc.

The first to third base resins BRS1, BRS2, and BRS3 may include a transparent organic material. For example, the first to third base resins BRS1, BRS2, and BRS3 may include an epoxy resin, an acrylic resin, a cardo resin, an imide resin, or the like. The first to third base resins BRS1, BRS2, and BRS3 may be made of, but is not limited to, the same material

The first wavelength-converting particles WCP1 may convert the blue light of the third color into the red light of the first color, and the second wavelength-converting particles WCP2 may convert the blue light of the third color into the green light of the second color. The first wavelength-converting particles WCP1 and the second wavelength-converting particles WCP2 may be quantum dots, quantum rods, phosphors, etc. The quantum dots may include IV nanocrystals, II-VI compound nanocrystals, III-V compound nanocrystals, IV-VI nanocrystals, or combinations thereof.

The color control structures TPL, WCL1, and WCL2 may be located directly on the second insulating layer PAS2. In the display device 10, the second bank BNL2 may have a height (e.g., a predetermined height) and may surround some regions, and the base resins BRS1, BRS2, and BRS3 of the color control structures TPL, WCL1, and WCL2 may be located directly on the light-emitting diodes ED and the second insulating layer PAS2 located thereon. The scattering particles SCP and wavelength conversion materials WCP1 and WCP2 of the color control structures TPL, WCL1, and WCL2 may be located in the respective base resins BRS1, BRS2, and BRS3 and may be located around the light-emitting diodes ED.

While the light-emitting diodes ED of different sub-pixels PXn may emit light of the same color (e.g., the blue light of the third color), the lights of different colors may exit from the different sub-pixels PXn. For example, the light emitted from the light-emitting diodes ED located in the first sub-pixel PX1 is incident on the first wavelength conversion layer WCL1, the light emitted from the light-emitting diodes ED located in the second sub-pixel PX2 is incident on the second wavelength conversion layer WCL2, and the light emitted from the light-emitting diodes ED located in the third sub-pixel PX3 is incident on the transparent layer TPL. The light incident on the first wavelength conversion layer WCL1 may be converted into red light, the light incident on the second wavelength conversion layer WCL2 may be converted into green light, and the light incident on the transparent layer TPL may transmit it as the same blue light without wavelength conversion. Although the sub-pixels PXn include the light-emitting diodes ED that emit light of the same color, light of different colors may be output by disposing the color control structures TPL, WCL1, and WCL2 over them.

A capping layer CPL is located on the color control structures TPL, WCL1, and WCL2. The capping layer CPL may be located to cover the color control structures TPL, WCL1, and WCL2 and the second insulating layer PAS2 on the second bank BNL2. The capping layer CPL may reduce or prevent the introduction of impurities such as moisture and air from the outside to damage or contaminate the color control structures TPL, WCL1, and WCL2. In addition, the capping layer CPL may reduce or prevent the spread of materials of the color control structures TPL, WCL1, and WCL2 to other elements. The capping layer CPL may be made of an inorganic material. It is to be noted that the capping layer CPL may be eliminated.

In addition, although not shown in the drawings, a plurality of layers may be further located on the capping layer CPL. For example, a low-refractive index layer as an optical layer and another capping layer covering the low-refractive index layer may be further located between the capping layer CPL and the color filter layers CFL1, CFL2, and CFL3.

Similar to the second insulating layer PAS2, the plurality of color filter layers CFL1, CFL2, and CFL3 may include a colorant such as a dye and a pigment that absorbs light in other wavelength ranges than light in a corresponding wavelength range. The color filter layers CFL1, CFL2, and CFL3 may be located in the sub-pixels PXn, respectively, to transmit only some of the lights incident on the color filter layers CFL1, CFL2, and CFL3 in the respective sub-pixels PXn. The sub-pixels PXn of the display device 10 may selectively display only the lights transmitted through the color filter layers CFL1, CFL2, and CFL3.

The first to third color filter layers CFL1, CFL2, and CFL3 may be located directly on the capping layer CPL. In addition, the first light-blocking member UBM overlapping the second bank BNL2 may be further located on the capping layer CPL.

The first light-blocking member UBM may be formed in a lattice pattern to partially expose one surface of the capping layer CPL. The first light-blocking member UBM may be located to cover the sub-areas SA of each of the sub-pixels PXn in addition to the second bank BNL2 when viewed from the top, and may be located to cover a part of the emission area EMA. The areas where the first light-blocking member UBM is not located may be the light-transmitting areas TA, wherein the color filter layers CFL1, CFL2, and CFL3 are located, and wherefrom light may exit.

The first light-blocking member UBM may be made of a material including an organic material. The first light-blocking member UBM may absorb external light, thereby reducing color distortion due to reflection of external light. According to some embodiments of the present disclosure, the first light-blocking member UBM may absorb all visible wavelengths. The first light-blocking member UBM may include a light-absorbing material. For example, the first light-blocking member UBM may be made of a material used as a black matrix of the display device 10.

Incidentally, in some embodiments, the first light-blocking member UBM may be eliminated from the display device 10, and may be substituted with a material that absorbs light of a corresponding wavelength among visible wavelengths and that transmits light of other wavelengths. The first light-blocking member UBM may be substituted with a color pattern including the same material as at least one of the first to third color filter layers CFL1, CFL2, and CFL3. For example, a color pattern including the material of one of the color filter layers may be located, or a plurality of color patterns may be stacked in place of the first light-blocking member UBM.

The first to third color filter layers CFL1, CFL2, and CFL3 are located on the capping layer CPL exposed by the first light blocking member UBM. The different color filter layers CFL1, CFL2, and CFL3 may be spaced apart from one another with respective portions of the first light-blocking member UBM therebetween, but the present disclosure is not limited thereto. In some embodiments, a part of the first to third color filter layers CFL1, CFL2, and CFL3 may be located on the first light-blocking member UBM, and may be spaced apart from one another on the first light-blocking member UBM. In other embodiments, the first to third color filter layers CFL1, CFL2, and CFL3 may partially overlap one another.

The color filter layers CFL1, CFL2, and CFL3 may include the first color filter layer CFL1 located in the first sub-pixel PX1, the second color filter layer CFL2 located in the second sub-pixel PX2, and the third color filter layer CFL3 located in third sub-pixel PX3. Unlike the color control structures TPL, WCL1, and WCL2, the first to third color filter layers CFL1, CFL2, and CFL3 may be formed in an island-like pattern conforming to the emission area EMA. It is, however, to be understood that the present disclosure is not limited thereto. The first to third color filter layers CFL1, CFL2, and CFL3 may form a linear pattern over the entire display area DPA.

According to some embodiments of the present disclosure, the first color filter layer CFL1 may be a red color filter layer, the second color filter layer CFL2 may be a green color filter layer, and the third color filter layer CFL3 may be a blue color filter layer. The light emitted from the light-emitting diodes ED may pass through the color control structures TPL, WCL1, and WCL2 to exit through the color filter layers CFL1, CFL2, and CFL3.

The light-emitting diodes ED located in the first sub-pixel PX1 may emit the blue light of the third color, and the light may be incident on the first wavelength conversion layer WCL1. The first base resin BRS1 of the first wavelength conversion layer WCL1 may be made of a transparent material, and some of the lights may pass through the first base resin BRS1 and may be incident on the capping layer CPL located thereon. At least some of the lights may be incident on the scattering particles SCP and the first wavelength-converting particles WCP1 dispersed in the first base resin BRS1. The light may be scattered, and the wavelength thereof may be converted into the wavelength of red light, such that the red light may be incident on the capping layer CPL. Lights incident on the capping layer CPL may pass through the capping layer CPL made of a transparent material, and may be incident on the first color filter layer CFL1. The first color filter layer CFL1 may block the transmission of other lights except red light. Accordingly, red light may be emitted from the first sub-pixel PX1.

Similarly, lights emitted from the light-emitting diodes ED located in the second sub-pixel PX2 may pass through the second wavelength conversion layer WCL2, the capping layer CPL, and the second color filter layer CFL2 to exit as green light.

The light-emitting diodes ED located in the third sub-pixel PX3 may emit the blue light of the third color, and the light may be incident on the transparent layer. The third base resin BRS3 of the transparent layer TPL may be made of a transparent material, and some of the lights may pass through the third base resin BRS3 and may be incident on the capping layer CPL located thereon. Lights incident on the capping layer CPL may pass through the capping layer CPL made of a transparent material, and may be incident on the third color filter layer CFL3. The third color filter layer CFL3 may block the transmission of other lights not including blue light. Accordingly, blue light may be emitted from the third sub-pixel PX3.

In some embodiments, at least one layer may be further located on the color filter layers CFL1, CFL2, and CFL3 and the first light-blocking member UBM. The layer located on the color filter layers CFL1, CFL2, and CFL3 and the first light-blocking member UBM may be a capping layer or an encapsulation layer protecting the elements. The capping layer or the encapsulation layer may be an inorganic layer or may have a stack structure of an inorganic layer and an organic layer. It is, however, to be understood that the present disclosure is not limited thereto.

Although the display device 10 according to some embodiments further includes the color filter layers CFL1, CFL2, and CFL3, it is possible to reduce or prevent the light that is incident from the outside and that passes through the color filter layers CFL1, CFL2, and CFL3 from being reflected and exiting by the second insulating layer PAS2.

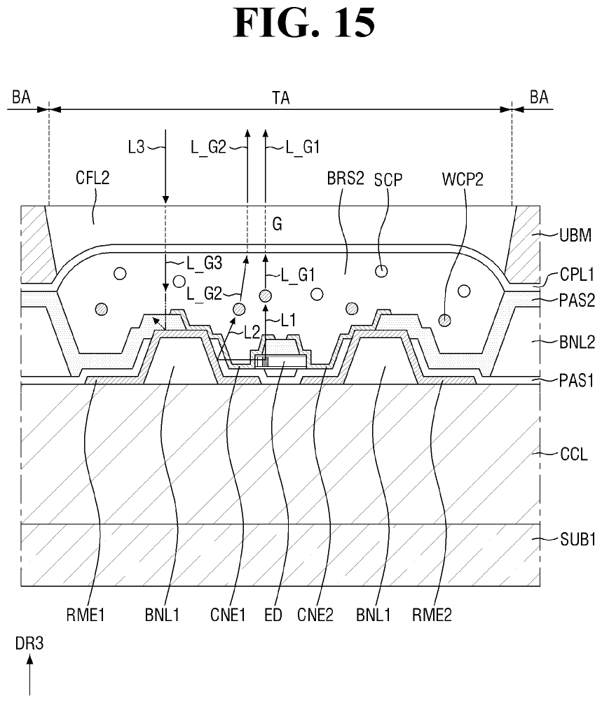

FIG. 15 is a cross-sectional view schematically showing paths of light in one of the sub-pixels of FIG. 14. FIG. 15 schematically shows paths through which the lights L1, L2, and L3 travel in the second sub-pixel PX2 in which the second wavelength conversion layer WCL2 and the second color filter layer CFL2 are located.

Referring to FIG. 15, the lights L1 and L2 emitted from the light-emitting diodes ED emitting blue light of the third color may exit through the second wavelength conversion layer WCL2 and the second color filter layer CFL2. The first light L1 emitted through side surface of the light-emitting diode ED passes through the second insulating layer PAS2 and is incident on the second wavelength conversion layer WCL2. Some of the lights are incident on the second wavelength-converting particles WCP2, are converted into light of the second color L_G1, and pass through the second color filter layer CFL2 to exit. The second light L2 emitted through the end surfaces of the light-emitting diode ED is reflected by the electrodes RME1 and RME2 located on the inclined side surface of the first bank BNL1, and is incident on the second wavelength conversion layer WCL2. Similar to the first light L1, a portion of the second light L2 is incident on the second wavelength converting particle WCP2, converted into a light of second color L_G2, and passes through the second color filter layer CFL2 to exit.

A third light L3 incident from the outside of the display device 10 may pass through the second color filter layer CFL2, and only light of the second color L_G3 may be incident on the second wavelength conversion layer WCL2. The light of the second color L_G3 incident from the outside may travel toward the second insulating layer PAS2 or toward the electrodes RME1 and RME2 without color conversion. Because the second insulating layer PAS2 blocks the transmission of the light with the exception of the light emitted from the light-emitting diode ED, that is, the blue light of the third color, the light of the second color L_G3 that is incident from the outside may be blocked or absorbed by the second insulating layer PAS2. Although display device 10 according to some embodiments includes only the light-emitting diodes ED that emit the blue light of the third color, the display device 10 may emit light of different colors as it may include the color control structures WCL1, WCL2 and TPL and the color filter layers CFL1, CFL2, and CFL3. Moreover, the display device 10 includes the second insulating layer PAS2 that transmits blue light of the third color emitted from the light-emitting diode ED while blocking the transmission of other lights, so that it is possible to more effectively reduce or prevent the reflection and exiting of the external light L3 having passed through the color filter layers CFL1, CFL2, and CFL3.

In concluding the detailed description, those skilled in the art will appreciate that many variations and modifications can be made to the disclosed embodiments without substantially departing from the aspects of the present disclosure. Therefore, the disclosed embodiments of the disclosure are used in a generic and descriptive sense only and not for purposes of limitation.

What is claimed is:

1. A display device comprising:
a first substrate;
a first electrode and a second electrode on the first substrate and spaced apart from each other;
a first insulating layer on the first electrode and the second electrode;
light-emitting elements on the first insulating layer and having ends on the first electrode and the second electrode, respectively; and
a second insulating layer on the first insulating layer and the light-emitting elements, and defining openings exposing the ends of the light-emitting elements,
wherein the second insulating layer is configured to transmit light in a wavelength range of light emitted by the light-emitting elements, and configured to block transmission of light outside of the wavelength range.

2. The display device of claim 1, wherein the light emitted from the light-emitting elements has a center wavelength range from about 400 nm to about 500 nm.

3. The display device of claim 1, wherein the openings of the second insulating layer comprise a first opening that exposes first ends of the light-emitting elements and that partially overlaps the first electrode, and a second opening that exposes second ends of the light-emitting elements and that partially overlaps the second electrode, and
wherein the second insulating layer comprises a pattern portion between the first opening and the second opening and on the light-emitting elements.

4. The display device of claim 3, wherein a thickness of the second insulating layer ranges from about 0.1 μm to about 1 μm.

5. The display device of claim 3, wherein a width of the pattern portion is less than a length of the light-emitting elements.

6. The display device of claim 3, further comprising:
a first contact electrode on the first electrode and the second insulating layer, and in contact with the first ends of the light-emitting elements; and
a second contact electrode on the second electrode and the second insulating layer, and in contact with the second ends of the light-emitting elements,
wherein the first contact electrode and the second contact electrode are spaced apart from each other on the pattern portion of the second insulating layer.

7. The display device of claim 6, wherein the first insulating layer exposes a part of an upper surface of each of the first electrode and the second electrode, and
wherein the first contact electrode and the second contact electrode are in direct contact with the first electrode and the second electrode, respectively.

8. The display device of claim 7, wherein the second insulating layer comprises parts directly on the first electrode and the second electrode.

9. The display device of claim 3, further comprising first banks between the first electrode and the first substrate, and between the second electrode and the first substrate, respectively,
wherein the first opening and the second opening partially overlap different ones of the first banks, respectively.

10. The display device of claim 1, further comprising a second bank on the first insulating layer, surrounding an emission area in which the light-emitting elements are located, and having a part of the second insulating layer thereon.

11. The display device of claim 10, wherein the second bank surrounds a sub-area spaced apart from the emission area and in which the light-emitting elements are not located,
wherein the first electrode and the second electrode are located across the emission area and the sub-area.

12. The display device of claim 11, wherein the first insulating layer comprises a first contact exposing a part of an upper surface of the first electrode in the sub-area, and a second contact exposing a part of an upper surface of the second electrode in the sub-area, and
wherein the second insulating layer further comprises a third opening overlapping the first contact, and a fourth opening overlapping the second contact.

13. The display device of claim 11, wherein the second insulating layer further comprises a fifth opening formed in the sub-area, and
wherein the first electrode and the second electrode are not located in the fifth opening.

14. The display device of claim 1, further comprising:
a wavelength conversion layer on the light-emitting elements; and
a color filter layer on the wavelength conversion layer, and configured to transmit light outside of the wavelength range of light emitted by the light-emitting elements, and to block transmission of light within the wavelength range of the light emitted by the light-emitting elements.

15. A display device comprising:
an emission area;
a sub-area spaced apart from the emission area in a first direction;
a first electrode and a second electrode extended in the first direction, and spaced apart from each other in a second direction;
a first insulating layer partially covering the first electrode and the second electrode;
light-emitting elements on the first electrode and the second electrode, and arranged in the first direction in the emission area; and
a second insulating layer on the first insulating layer and on the light-emitting elements, defining openings exposing ends of the light-emitting elements, and comprising a pattern portion extended in the first direction between the openings and on the light-emitting elements,
wherein the light emitted from the light-emitting elements has a central wavelength range from about 400 nm to about 500 nm, and
wherein the second insulating layer is configured to transmit light having a central wavelength range from about 400 nm to about 500 nm while blocking other lights.

16. The display device of claim 15, wherein the second insulating layer is on the emission area and the sub-area, and defines a first opening extended in the first direction and partially overlapping the first electrode, and a second opening extended in the first direction and partially overlapping the second electrode in the emission area.

17. The display device of claim 16, wherein the first insulating layer comprises a first contact exposing a part of an upper surface of the first electrode, and a second contact exposing a part of an upper surface of the second electrode in the sub-area, and
wherein the second insulating layer further defines a third opening overlapping the first contact, and a fourth opening overlapping the second contact.

18. The display device of claim 17, further comprising:
a first contact electrode on the first electrode, and in contact with first ends of the light-emitting elements exposed by the first opening and with the first electrode exposed by the third opening and the first contact; and
a second contact electrode on the second electrode, and in contact with second ends of the light-emitting elements exposed by the second opening and with the second electrode exposed by the fourth opening and the second contact.

19. The display device of claim 16, wherein the second insulating layer further defines a fifth opening formed in the sub-area, and
wherein the first electrode and the second electrode are not located in the fifth opening.

20. The display device of claim 15, wherein a width of the pattern portion is less than a length of the light-emitting elements.
